(19) United States
(12) Patent Application Publication
(10) Pub. No.: US 2008/0297535 A1
(43) Pub. Date: Dec. 4, 2008

(54) Terminal device for presenting an improved virtual environment to a user

(75) Inventor: Karl Reinig, Denver, CO (US)

Correspondence Address: PATTON BOGGS LLP, 1801 CALFORNIA STREET, SUITE 4900, DENVER, CO, 80202, US

(73) Assignee: Touch of Life Technologies, Aurora, CO (US)

(21) Appl. No.: 11/809,003

(22) Filed: May 30, 2007

(51) Int. Cl. G09G 5/00; H03K 17/94

(52) U.S. Cl. 345/633; 340/407.1; 345/9

(57) ABSTRACT

The virtual environment terminal device comprises a user terminal device that interfaces the user to a computer controlled virtual reality system via the sense of touch by applying forces, vibrations, and/or motions to the user to emulate the sensations that the user would encounter in the environment emulated by the virtual reality system while also providing a three-dimensional image of the workspace by using a view splitting device to display the screens of two different monitors to respective ones of the user's two eyes.

### FIELD OF THE INVENTION

This invention relates to a user terminal device that interfaces the user to a computer controlled virtual reality system via the sense of touch by applying forces, vibrations, and/or motions to the user to emulate the sensations that the user would encounter in the environment emulated by the virtual reality system while also providing a three-dimensional image of the workspace by using a view splitting device to display the screens of two different monitors to respective ones of the user's two eyes.

### BACKGROUND OF THE INVENTION

It is a problem in the field of virtual reality to provide the user both with adequate and reliable tactile feedback as well as a three-dimensional image of the workspace thereby to provide the user with a realistic representation of the emulated environment. Thus, the problem has two components: one being tactile and the other visual.

On the tactile side of this problem, haptics is the science of applying touch (tactile) sensation and control to a user's interaction with computer applications. By using special input/output devices (joysticks, data gloves, or other devices), users can receive feedback from computer applications in the form of felt sensations in the hand or other parts of the body. In combination with a visual display, haptics technology can be used to train people for tasks requiring hand-eye coordination, such as surgery and space ship maneuvers. It can also be used for games in which users feel as well as see their interactions with images. Haptics, therefore, offers an additional dimension to a virtual reality or three-dimensional environment.

Tele-operators are remote controlled robotic tools, and when contact forces are reproduced to the operator, it is called “haptic tele-operation”. “Force feedback” is used in all kinds of tele-operators such as underwater exploration devices controlled from a remote location. When such devices are simulated using a computer (as they are in operator training devices), it is useful to provide the force feedback that would be felt in actual operations. Since the objects being manipulated do not exist in a physical sense, the forces are generated using haptic (force generating) operator controls. Data representing touch sensations may be saved or played back using such haptic technologies.

Various haptic interfaces for medical simulation may prove especially useful for training of minimally invasive procedures (laparoscopy/interventional radiology) and remote surgery using tele-operators. In the future, expert surgeons may work from a central workstation, performing operations in various locations, with machine setup and patient preparation performed by local nursing staff. Rather than traveling to an operating room, the surgeon instead becomes a tele-presence. A particular advantage of this type of work is that the surgeon can perform many more operations of a similar type with less fatigue. It is well documented that a surgeon who performs more procedures of a given kind statistically has better outcomes for his patients.

On the visual side of this problem, the user must be presented with a realistic representation of the emulated environment. One method of providing a virtual three-dimensional representation is the use of reflective devices, which have long been used to create an apparent image of an object at some distance from that object. Locating an apparition next to a passenger in Disneyland's Pirates of the Caribbean^{SM} is an example experienced by many since the 1950s. This same technology has been used to create an apparent collocation of haptic devices and computer graphics since SensAble Technologies, Inc. began marketing its line of commercially available haptic devices in the early 1990s. The University of Colorado Center for Human Simulation was one of the early groups to demonstrate this technology publicly, including display of such a system at the 1998 annual meeting of the ACM's Significant Interest Group on Graphics (SIGGRAPH) in Orlando, Fla. Many others have created similar haptic systems.

These commercially available systems generally use a single stereo capable monitor to produce a stereoscopic view of the environment. Cathode Ray Tube (CRT) monitors are currently the most popular display device for such systems. They are the only commonly available display device capable of refreshing the screen at the high frequency desirable for quality shuttered stereo display. The high frequency is desirable since splitting the monitor temporally reduces the apparent refresh rate seen by each eye by a factor of two. Thus, for one eye to see a refresh rate of 60 Hz, the monitor must be refreshing at 120 Hz.

The use of commercially available computer displays greatly reduces the cost of the virtual environments. However, the use of CRT displays requires the use of shuttered glasses to give separate images to each eye and has significant disadvantages. The view received by each eye is occluded for roughly half the time. CRT monitors are far larger and heavier than Liquid Crystal Display (LCD) monitors having the same screen area. In addition, CRT monitors are rapidly losing their market to LCD monitors, raising their expense and possibly leading to their extinction.

### BRIEF SUMMARY OF THE INVENTION

The above-described problems are solved and a technical advance achieved by the present Terminal Device For Presenting An Improved Virtual Environment To A User, termed “virtual environment terminal device” herein. The virtual environment terminal device provides an alternative to using CRT displays for producing a stereo display of a scene, which can be collocated with the haptic display. The virtual environment terminal device consists of a view splitting device that delivers the display present on separate computer monitors into a corresponding one of the user's two eyes. The view splitting device and the associated monitors can be located such that the apparent stereo pair may be placed where desired in the virtual environment. By splitting the presentation of the view that each eye sees to separate monitors, each of the user's eyes sees the full resolution of each monitor at all times. This gives the potential for significantly higher spatial and temporal resolution, resulting in a significant improvement of the stereo graphic display.

One embodiment of the virtual environment terminal device places the monitors the same distance from the view splitting device as the distance from the view splitting device to the center of the workspace of one or more haptic devices. This embodiment places the focal distance of the three-dimensional image presented by the view splitting device in the center of the haptic workspace, minimizing the strain on the user's eyes due to mismatch of the two focal points.

The view splitting device and haptic devices can be affixed to a common frame and rotated together, thereby allowing the collocated working area to be displayed to the user in a wide variety of orientations. One embodiment of this configuration allows the scene presented to the user to be rotated from appearing to be below the user's head to one at the user's eye level, such as for the simulation of medical procedures in which the virtual patient is lying on a table with the scene being rotated up to match the ergonomics of the user providing a joint injection into the virtual patient's shoulder.

Another embodiment of the virtual environment terminal device places monocular eyepieces in front of the view splitting device. The monocular eyepieces give the user the sensation of looking through a binocular microscope and can be used for producing a virtual environment in which the user can practice ophthalmic surgery or neurosurgery.

### BRIEF DESCRIPTION OF THE DRAWINGS

FIG. 1 illustrates the overall architecture of the present virtual environment terminal device;

FIG. 2 illustrates one embodiment of the present virtual environment terminal device;

FIGS. 3A-3C illustrate various examples of the accommodation-convergence conflict; and

FIG. 4 illustrates a typical augmented reality display for haptics-based applications which uses half-silvered mirrors to create virtual projection planes that are collocated with the haptic device workspaces.

### DETAILED DESCRIPTION OF THE INVENTION

### Categories of Virtual Reality Systems

Rear-projection-based virtual reality (VR) devices create a virtual environment by projecting stereoscopic images on screens located between the users and the image projectors. These displays suffer from occlusion of the image by the user's hand or any interaction device located between the user's eyes and the screens. When a virtual object is located close to the user, the user can place their hand “behind” the virtual object. However, the hand always looks “in front” of the virtual object because the image of the virtual object is projected on the screen. This visual paradox confuses the brain and breaks the stereoscopic illusion.

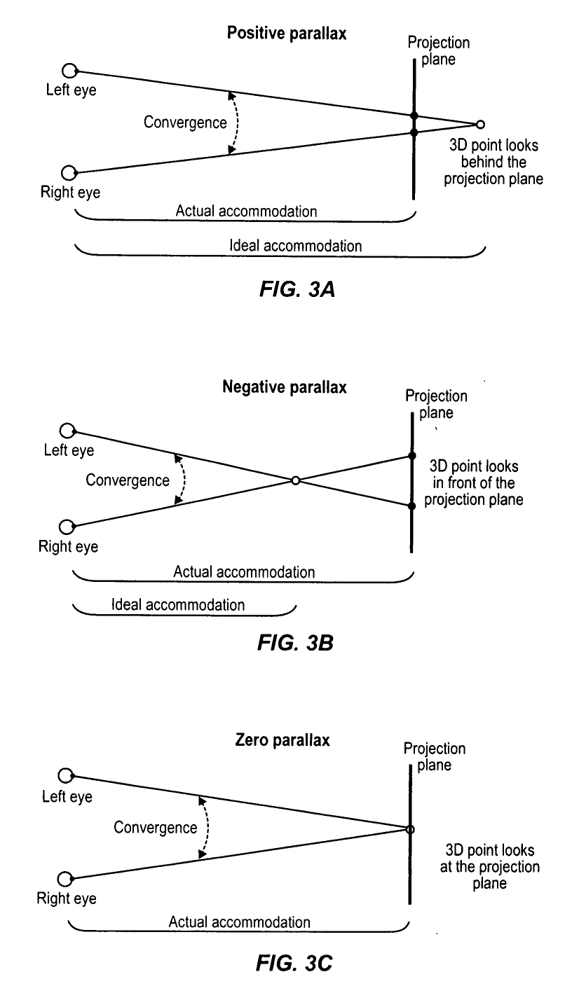

Another problem of regular virtual reality devices displaying stereo images is known as the “accommodation/convergence conflict” (FIGS. 3A-3C). The accommodation is the muscle tension needed to change the focal length of the eye lens in order to focus at a particular depth. The convergence is the muscle tension to rotate both eyes so that they are facing the focal point. In the real world, when looking at distant objects, the convergence angle between both eyes approaches zero and the accommodation is minimum (the cornea compression muscles are relaxed). When looking at close objects, the convergence angle increases and the accommodation approaches its maximum. The brain coordinates the convergence and the accommodation. However, when looking at stereo computer-generated images, the convergence angle between eyes still varies as the three-dimensional object moves back and forward, but the accommodation always remains the same because the distance from the eyes to the screen is fixed. When the accommodation conflicts with the convergence, the brain gets confused and causes headaches.

In computer graphics, the stereo effect is achieved by defining a positive (FIG. 3A), negative (FIG. 3B), or zero parallax according to the position of the virtual object with respect to the projection plane. Only when the virtual object is located on the screen (zero parallax) is the accommodation/converge conflict eliminated (FIG. 3C). In most augmented reality systems, since the projection plane is not physical, this conflict is minimized because the user can grab virtual objects with their hands nearby, or even exactly at, the virtual projection plane.

### Haptic Systems

The purpose of virtual reality and simulation since its beginnings has been “to create the illusion so well that you feel you are actually doing it.” While this goal is still actively being pursued, the past ten years have shown a steady evolution in virtual reality technologies. Virtual reality technology is now being used in many fields. Air traffic control simulations, architectural design, aircraft design, acoustical evaluation (sound proofing and room acoustics), computer aided design, education (virtual science laboratories, cost effective access to sophisticated laboratory environments), entertainment (a wide range of immersive games), legal/police (re-enactment of accidents and crimes), medical applications such as virtual surgery, scientific visualization (aerodynamic simulations, computational fluid dynamics), telepresence and robotics, and flight simulation are among its applications.

Until recently, the one major component lacking in virtual reality simulations has been the sense of touch (haptics). In the pre-haptic systems, a user could reach out and touch a virtual object, but would not actually feel the contact with the object, which reduces the reality effect of the environment. Haptics provide force feedback With force feedback, a user gets the sensation of physical mass in objects presented in the virtual world composed by the computer. Haptic systems are essentially in their infancy, and improvements may still be achieved. The systems can be expensive and may be difficult to produce.

A number of virtual reality systems have been developed previously. The systems generally provide a realistic experience, but have limitations. Example issues in prior systems include, for example, user occlusion of the graphics volume, visual acuity limitations, large mismatch in the size of graphics and haptics volumes, and unwieldy assemblies.

### Augmented Reality Displays

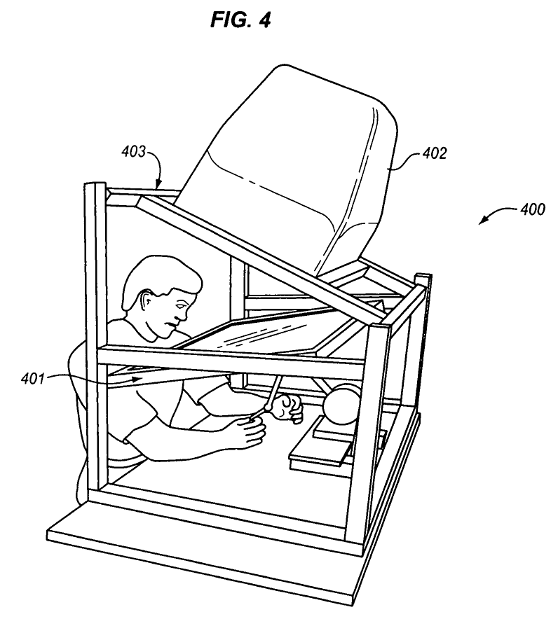

Augmented reality displays 400 are more suitable for haptics-based applications because, instead of projecting the images onto physical screens, they use half-silvered mirrors 401 to create virtual projection planes that are collocated with the haptic device workspaces (FIG. 4). A display 402 is mounted on a frame 403 above the user's head, and the image generated by the display is projected on to the half-silvered mirror 401. The user's hands, located behind the mirror 401, are integrated with the virtual space and provide a natural means of interaction. The user can still see their hands without occluding the virtual objects.

The stereo effect in computer graphics displays is achieved by defining a positive, negative, or zero parallax according to the position of the virtual object with respect to the projection plane. Only when the virtual object is located on the screen (zero parallax) is the accommodation/converge conflict eliminated. Most augmented reality systems do a fair job of minimizing this conflict. Since the projection plane is not physical, the user can grab virtual objects with their hands nearby, or even exactly at, the virtual projection plane.

However, conflicts can still arise for a number of reasons. If head tracking is not used or fails to accommodate a sufficient range of head tracking, then collocation of the graphics and haptics is lost. In systems with head tracking, if the graphics recalculation is slow, then conflicts arise. In systems lacking head tracking, conflicts arise with any user movement. Systems that fail to permit an adequate range of movement tracking can cause conflicts to arise as well, as can systems that do not properly position a user with respect to the system. The latter problem is especially prevalent in systems requiring a user to stand.

### PARIS™ Display

PARIS™ is a projection-based augmented reality system developed by researchers at the University of Illinois at Chicago that uses two mirrors to fold the optical path and transmit the image to a translucent black rear-projection screen, illuminated by a Christie Mirage 2000 stereo DLP projector. A user stands and looks through an inclined half-silvered mirror that reflects an image projected onto a horizontal screen located above the user's head. A haptics volume is defined below the inclined half-silvered mirror, and a user can reach their hands into the haptics volume.

The horizontal screen is positioned outside of an average sized user's field of view, with the intention that only the reflected image on the half-silvered mirror is viewable by the user when the user is looking at the virtual projection plane. Because the half-silvered mirror is translucent, the brightness of the image projected on the horizontal screen is higher than the brightness of the image reflected by the mirror. If the user is positioned such that the image on the horizontal screen enters the field of view, the user can be easily distracted by the horizontal screen.

An issue in haptic augmented reality systems is maintaining collocation of the graphical representation and the haptic feedback of the virtual object. To maintain certain realistic eye-hand coordination, a user has to see and touch the same three-dimensional point in the virtual environment. In the PARIS™ system, collocation is enhanced by a head and hand tracking system handled by a dedicated networked “tracking” computer. Head position and orientation is continuously sent to a separate “rendering” PC over a network to display a viewer-centered perspective. In the PARIS™ system, the tracking PC uses a pcBIRD from Ascension Technologies Corp. for head and hand tracking.

The PARIS™ system uses a large screen (58″×47″), and provides 120° of horizontal field of view. The wide field of view provides a high degree of immersion. The maximum projector resolution is 1280×1024 at 108 Hz. With the large screen used in the PARIS™ system, the pixel density (defined as the ratio resolution/size) is 22 pixels per inch (ppi), which is too low to distinguish small details.

The PARIS™ system uses a SensAble Technologies' PHANTOM® Desktop™ haptic device, which presents a haptics workspace volume that approximates a six-inch cube. The graphics workspace volume exceeds the haptics volume considerably. This mismatch of haptics and graphics volume results in only a small portion of the virtual space to be touched with the haptic device. Additionally with the mismatched volumes, only a small number of pixels are used to display the collocated objects.

The PARIS™ system use of an expensive stereo projector, and its large screen and half-silvered mirror, requires use of a cumbersome support assembly. This support assembly and the system as a whole do not lend themselves to ready pre-assembly, shipping, or deployment.

### Reachin Display

The Reachin display is a low-cost CRT-based augmented reality system. A small desktop-sized frame holds a CRT above a small half-silvered mirror that is slightly smaller in size than the 17″ CRT. The CRT monitor has a resolution of 1280×720 at 120 Hz. Since the CRT screen is 17″ diagonal, the pixel density is higher than that of the PARIS™ system: approximately 75 ppi. However, the image reflected on the mirror is horizontally inverted; therefore, the Reachin display cannot be used for application development without using some sort of text inversion. Reachin markets a proprietary applications programming interface (API) to display properly inverted text on virtual buttons and menus along with the virtual scene.

The Reachin display lacks head tracking. The graphics/haptics collocation is only achieved at a particular sweet spot, and it is rapidly lost as the user moves his/her head to the left or right looking at the virtual scene from a different angle. In addition, the image reflected on the mirror gets out of the frame because the mirror is so small. The position of the CRT is also in the field of view of the user, which is very distracting.

### SenseGraphics 3D-MIW

SenseGraphics is a portable auto-stereoscopic augmented reality display suitable for on-the-road demonstrations. A Sharp Actius RD3D laptop is used to display three-dimensional images without requiring the wearing of stereo goggles. It is relatively inexpensive and very compact. The laptop is mounted such that its display generally is parallel to and vertically above a like-sized half-silvered mirror. Like most auto-stereoscopic displays, the resolution in three-dimensional mode is too low for detailed imagery, as each eye sees only 512×768 pixels. The pixel density is less than 58 ppi. In addition, any variation from the optimal position of the head causes the stereo to be lost and even reversed. The laptop display has its lowest point near the user and is inclined away toward the back of the system This is effective in making sure that the display of the laptop is outside the view of a user. However, there is a short distance between the laptop display and the mirror. This makes the user's vertical field of view too narrow to be comfortable. Also, as in the Reachin display, the image is inverted, so it is not well-suited for application development. Recently, SenseGraphics has introduced 3D-LIW, which has a wider mirror, however, the other limitations still exist.

### Virtual Environment Terminal Device Architecture

An embodiment of the virtual environment terminal device is a compact haptic and augmented virtual reality system that produces an augmented reality environment. The system is equipped with software and devices that provide users with stereoscopic visualization and force feedback simultaneously in real time. High resolution, high pixel density, and head and hand tracking ability are provided to realize well-matched haptics and graphics volumes. The virtual environment terminal device is compact, making use of a standard personal display device as the display driver, which reduces the cost of implementation compared to many conventional virtual reality systems.

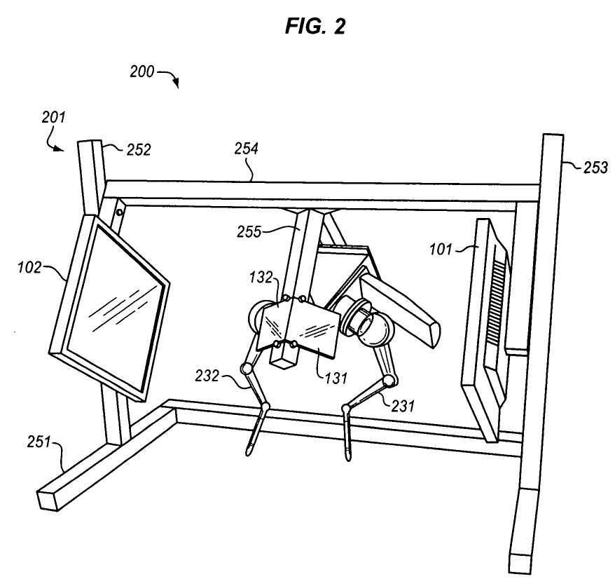

The virtual environment terminal device produces visual acuity approaching 20/20. In addition, collocation of the haptic display and haptic workspace is maintained. User comfort is maintained by the provision of well-matched graphics and haptic volumes, a comfortable user position, and real-time updating of graphics and the haptics environment. FIG. 2 illustrates a compact haptic and augmented virtual reality system that provides high resolution, high pixel density, and perfectly matching haptics and graphics volumes. A highly realistic virtual environment is provided and user fatigue, dizziness, and headaches thereby are reduced or eliminated.

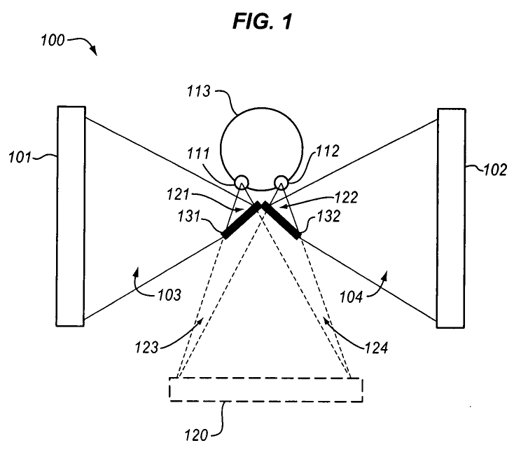

FIG. 1 illustrates the overall architecture of the split screen display 100 of the present virtual environment terminal device. The user 113 is positioned in front of a view splitting device 131, 132 and the associated pair of monoscopic monitors 101, 102, such that each of the user's eyes 111, 112 receives only the display that is generated on the associated one of the two monoscopic monitors 101, 102. Thus, each of the user's eyes 111, 112 focuses on the associated reflective surface 131, 132, respectively, of the view splitting device, which displays the image projected 103,104, respectively, by the associated monoscopic monitor 101, 102, respectively.

The presentation of two different images in this manner enables the virtual environment terminal device 100 to provide the user 113 with an apparent stereo three-dimensional view 120 of a particular workspace. The apparent view provided to the user's eyes 111, 112 is the user's field of view 121,122, virtually extended along paths 123, 124 to the apparent stereo three-dimensional view 120 of a particular workspace.

The placement of the two monoscopic monitors 101, 102 in a substantially parallel spaced-apart relationship with respect to each other and substantially perpendicular to (and equidistant from) the user's field of view 121,122 enables the virtual environment terminal device 100 to minimize the apparatus that is placed in the user's field of view 121, 122, since the monitors 101,102 are outside of the user's field of view 121,122. In addition, by splitting the view that each eye 111, 112 sees to separate monitors 101, 102, each of the user's eyes 111, 112 sees the full resolution of each monitor 101, 102 at all times. This gives the potential for significantly higher spatial and temporal resolution, resulting in a significant improvement of the stereo graphic display.

### Virtual Environment Terminal Device Embodiment

FIG. 2 illustrates one embodiment of the present virtual environment terminal device 200. This embodiment places each of the monitors 101, 102 the same distance from the view splitting device 131, 132 as the distance to the center of the workspace of one or more haptic devices 231, 232. This embodiment places the focal distance to the monitors 101, 102 in the center of the haptic workspace, minimizing the eye strain due to mismatch of the two.

The virtual environment terminal device 200 includes a frame 201 that consists of a base element 251 that can be placed on a work table or bench to which two vertical supports 252, 253 are attached. A transverse member 254 can be pivotally attached at its ends to respective ones of the two vertical supports 252, 253 to enable the user to rotate the haptic device 231, 232 and the associated monitors 101, 102 about the axis of the transverse member 254. In addition, the haptic device 231, 232 can be attached rotationally to the transverse member 254 so that the haptic device 231, 232 can be rotated about the axis of attachment, thereby enabling the user to rotate the haptic device 231, 232 in all three planes thereby to adjust the orientation of the haptic device 231, 232. Furthermore, the frame 201 can be attached to an adjustable support, such as a table that can be height adjusted and tilted thereby to enable the user to create an ergonomically correct work environment customized for the user's physical characteristics.

The view splitting device and haptics workspace can be rotated together via rotation of transverse member 254 allowing the collocated working area to be displayed in a wide variety of orientations. One embodiment of this allows the scene to be rotated from appearing to be below the user's head, for the simulation of procedures in which the virtual patient is lying on a table, to the scene being rotated up to match the ergonomics of joint injection of a shoulder.

Another embodiment (not shown) places monocular eyepieces in front of the view splitting device. The monocular eyepieces give the user the sensation of looking through a binocular microscope and can be used for producing a virtual environment in which to practice ophthalmic surgery or neurosurgery.

### SUMMARY

The user terminal device interfaces the user to a computer controlled virtual reality system via the sense of touch by applying forces, vibrations, and/or motions to the user to emulate the sensations that the user would encounter in the environment emulated by the virtual reality system, while also providing a three-dimensional image of the workspace by using a view splitting device to display the screens of two different monitors to respective ones of the user's two eyes.

What is claimed as new and desired to be protected by Letters Patent of the United States is:

1. A virtual environment terminal device for interfacing the user to a computer controlled virtual reality system via at least one of the user's senses, comprising:
at least one haptic device for emulating the sensations that the user would encounter in the workspace environment emulated by the virtual reality system; and
image means for providing a three-dimensional image of the emulated workspace, comprising:
first monitor means for generating an image of the emulated workspace for display to a first of said user's eyes,
second monitor means for generating an image of the emulated workspace for display to a second of said user's eyes, and
view splitting means for transmitting the images displayed on said first and second monitor means to said first and said second user's eyes, respectively,
wherein said first monitor means and said second monitor means are in a substantially parallel spaced-apart relationship with respect to each other and located substantially perpendicular to the user's field of view and on either side of said view splitting means.

2. The virtual environment terminal device of claim 1 wherein said image means is interposed between said workspace environment emulated by the virtual reality system and said user.

3. The virtual environment terminal device of claim 1 wherein said first monitor means produces a monocular image of the emulated workspace for display to a respective first one of the user's two eyes.

4. The virtual environment terminal device of claim 3 wherein said second monitor means produces a monocular image of the emulated workspace for display to a respective second one of the user's two eyes.

5. The virtual environment terminal device of claim 1 further comprising:
frame means attached to said view splitting device and said at least one haptic device to enable said view splitting device and said at least one haptic device to be rotated together, thereby allowing the collocated workspace environment to be displayed to the user in a wide variety of orientations.

6. The virtual environment terminal device of claim 5 further comprising:
wherein said first monitor means is attached to said frame means for generating an image of the emulated workspace for display to a first of said user's eyes; and
wherein said second monitor means is attached to said frame means for generating an image of the emulated workspace for display to a second of said user's eyes.

7. The virtual environment terminal device of claim 6 wherein said view splitting means comprises:
first reflective surface means located in an optical path that exists from said first one of the user's eyes to said workspace environment emulated by the virtual reality system; and
second reflective surface means located in an optical path that exists from said second one of the user's eyes to said workspace environment emulated by the virtual reality system.

8. The virtual environment terminal device of claim 1 wherein said first monitor means and said second monitor means are located a distance from said user equal to the focal distance of the three-dimensional image presented by the view splitting device in the center of the haptic workspace.

9. A virtual environment terminal device for interfacing the user to a computer controlled virtual reality system via at least one of the user's senses, comprising:
frame means;
at least one haptic device for emulating the sensations that the user would encounter in the workspace environment emulated by the virtual reality system; and
image means attached to said frame means and interposed between said workspace environment emulated by the virtual reality system and said user for providing a three-dimensional image of the emulated workspace, comprising:
first monitor means attached to said frame means for generating an image of the emulated workspace for display to a first of said user's eyes,
second monitor means attached to said frame means for generating an image of the emulated workspace for display to a second of said user's eyes, and
view splitting means for transmitting the images displayed on said first and second monitor means to said first and said second user's eyes, respectively,
wherein said first monitor means and said second monitor means are in a substantially parallel spaced-apart relationship with respect to each other, located substantially perpendicular to the user's field of view and on either side of said view splitting means; and
wherein said frame means includes view rotation means attached to said view splitting device, to enable said view splitting device and said monitors to be rotated, thereby allowing the workspace environment emulated by the virtual reality system to be displayed to the user in a wide variety of orientations.

10. The virtual environment terminal device of claim 9 wherein said image means is interposed between said workspace environment emulated by the virtual reality system and said user.

11. The virtual environment terminal device of claim 9 wherein said first monitor means produces a monocular image of the emulated workspace for display to a respective first one of the user's two eyes.

12. The virtual environment terminal device of claim 11 wherein said second monitor means produces a monocular image of the emulated workspace for display to a respective second one of the user's two eyes.

13. The virtual environment terminal device of claim 9 wherein said view splitting means comprises:
first reflective surface means located in an optical path that exists from said first one of the user's eyes to said workspace environment emulated by the virtual reality system; and
second reflective surface means located in an optical path that exists from said second one of the user's eyes to said workspace environment emulated by the virtual reality system.

14. The virtual environment terminal device of claim 9 wherein said first monitor means and said second monitor means are located a distance from said user equal to the focal distance of the three-dimensional image presented by the view splitting device in the center of the haptic workspace.
